(19) United States
(12) Patent Application Publication
(10) Pub. No.: US 2025/0055438 A1
(43) Pub. Date: Feb. 13, 2025

(54) RESONATOR AND RESONATOR DRIVE METHOD

(71) Applicant: DB HiTek Co., Ltd., Seoul (KR)

(72) Inventor: Jung Ah KIM, Eumseong-gun (KR)

(73) Assignee: DB HiTek Co., Ltd., Seoul (KR)

(21) Appl. No.: 18/427,186

(22) Filed: Jan. 30, 2024

(30) Foreign Application Priority Data
Aug. 9, 2023 (KR) 10-2023-0104222

(51) Int. Cl. H03H 9/02; H03H 9/10; H03H 9/24

(52) U.S. Cl. CPC H03H 9/02259; H03H 9/02393; H03H 9/1057; H03H 9/2447

(57) ABSTRACT

A resonator drive method is provided. The resonator drive method comprises: driving a third electrode that is higher than the first electrode and the second electrode based on an upper surface of the substrate, which are spaced apart from each other at a first interval on a substrate, to descend toward the substrate; and arranging the third electrode between the first electrode and the second electrode to be in contact with the upper surface of the substrate and arranging the first electrode, the second electrode, and the third electrode to be spaced apart from one another at a second interval, wherein the second interval is less than the first interval.

### CROSS-REFERENCE TO RELATED APPLICATION

This application is based on and claims priority under 35 U.S.C. § 119 to Korean Patent Application No. 10-2023-0104222, filed on Aug. 9, 2023, in the Korean Intellectual Property Office, the disclosure of which is incorporated by reference herein in its entirety.

### BACKGROUND

The present disclosure relates to a resonator and a resonator drive method, and particularly, to a resonator capable of generating a plurality of resonance frequencies and a resonator drive method.

Descriptions herein simply provide background information on the present embodiments and do not constitute conventional technology.

In wireless communication systems, various devices including resonators are used to construct RF circuits. In particular, resonators that operate only in a single band may be required in proportion to the number of frequency bands required to configure a multi-band system. In this case, problems, such as an increase in size of a device and a decrease in degree of integration may occur.

### SUMMARY

An object of the present disclosure is to provide a resonator capable of generating a plurality of resonance frequencies and a resonator drive method.

Object of the present disclosure are not limited to the object described above, and other objects and advantages of the present disclosure that are not described may be understood through following descriptions and will be more clearly understood by embodiments of the present disclosure. Also, it will be readily apparent that the objects and advantages of the present disclosure may be implemented by the device and method indicated in the patent claims and combinations thereof.

A resonator and a resonator drive method of the present disclosure may increase integration without increasing a size of the resonator by providing a structure and a drive method of a resonator that may generate a plurality of resonance frequencies.

Also, the resonator and the resonator drive method of the present disclosure may generate a plurality of resonance frequencies with a simple operation by providing a structure and drive method of a resonator, and thus, convenience is increased.

According to some aspects of the disclosure, a resonator comprise; a substrate, a first electrode and a second electrode disposed on the substrate at a first interval, a plurality of arrangement electrodes disposed on the substrate, including the first electrode and the second electrode, and changing included electrodes based on a state, an actuator configured to adjust an interval between the plurality of arrangement electrodes, and a third electrode driven by the actuator and located between the first electrode and the second electrode, wherein, in a first state, the third electrode is higher than the first electrode and the second electrode based on an upper surface of the substrate, and the plurality of arrangement electrodes include the first electrode and the second electrode spaced apart from each other at the first interval, in a second state, the third electrode is moved toward the substrate by the actuator to be disposed between the first electrode and the second electrode on the substrate, and the first electrode, the second electrode, and the third electrode are spaced apart from one another at a second interval less than the first interval, and the plurality of arrangement electrodes include the first electrode, the second electrode, and the third electrode.

According to some aspects, in the first state, a first resonance frequency of the resonator is determined based on the interval between the plurality of arrangement electrodes being the first interval, in the second state, a second resonance frequency of the resonator is determined based on the interval between the plurality of arrangement electrodes being the second interval, and the second resonance frequency is higher than the first resonance frequency.

According to some aspects, the third electrode is located on one side of the second electrode, the resonator further includes a fourth electrode driven by the actuator and located on another side of the second electrode, in the first state, the fourth electrode is higher than the first electrode and the second electrode based on the upper surface of the substrate, in the second state, the fourth electrode is moved toward the substrate by the actuator to be disposed on another side of the second electrode on the substrate, and the second electrode and the fourth electrode, which are adjacent to each other, are spaced apart from each other at the second interval, and the plurality of arrangement electrodes include the first electrode, the second electrode, the third electrode, and the fourth electrode.

According to some aspects, in the second state, the first electrode, the second electrode, the third electrode, and the fourth electrode are in direct contact with the upper surface of the substrate.

According to some aspects, in the second state, the first electrode, the second electrode, and the third electrode are in direct contact with the upper surface of the substrate.

According to some aspects, a fourth electrode driven by the actuator and located in parallel with the third electrode, wherein, in the first state, the fourth electrode is higher than the first electrode and the second electrode based on the upper surface of the substrate, and in the second state, the fourth electrode is spaced apart from the upper surface of the substrate and is higher than the first electrode, the second electrode, and the third electrode.

According to some aspects, in the second state, the first electrode, the second electrode, and the third electrode are in direct contact with the upper surface of the substrate.

According to some aspects of the disclosure, a resonator of claim 1, further comprise; a fourth electrode driven by the actuator and located in parallel to the third electrode, wherein, in the first state, the fourth electrode is higher than the first electrode and the second electrode based on the upper surface of the substrate, in the third state, the third electrode and the fourth electrode are driven by the actuator to move along a direction parallel to the upper surface of the substrate and a direction toward the substrate and disposed between the first electrode and the second electrode on the substrate, and the first electrode, the second electrode, the third electrode, and the fourth electrode are spaced apart from one another at a third interval less than the first interval and the second interval, and the plurality of arrangement electrodes include the first electrode, the second electrode, the third electrode, and the fourth electrode.

According to some aspects, in the first state, the fourth electrode is closer than the second electrode than the third electrode.

According to some aspects, in the first state, a first resonance frequency of the resonator is determined based on the interval between the plurality of arrangement electrodes being the first interval, in the second state, a second resonance frequency of the resonator is determined based on the interval between the plurality of arrangement electrodes being the second interval, in the third state, a third resonance frequency of the resonator is determined based on the interval between the plurality of arrangement electrodes being the third interval, and the third resonance frequency is higher than the second resonance frequency, and the second resonance frequency is higher than the first resonance frequency.

According to some aspects, in the third state, the first electrode, the second electrode, the third electrode, and the fourth electrode are in direct contact with the upper surface of the substrate.

According to some aspects of the disclosure, a resonator of claim 1, further comprise; a fourth electrode driven by the actuator and located in parallel to the third electrode, wherein, in the first state, the fourth electrode is higher than the first electrode and the second electrode based on the upper surface of the substrate, In the second state, the third electrode is driven by the actuator to move in a direction parallel to the upper surface of the substrate and then move toward the substrate such that an interval between the first electrode and the third electrode is the second interval, and the fourth electrode is driven by the actuator to move in the direction parallel to the upper surface of the substrate and then move toward the substrate such that an interval between the second electrode and the fourth electrode is the second interval, and the second electrode is disposed between the third electrode and the fourth electrode.

According to some aspects, in the second state, the first electrode, the second electrode, the third electrode, and the fourth electrode are in direct contact with the upper surface of the substrate.

According to some aspects, in the first state, a first resonance frequency of the resonator is determined based on the interval between the plurality of arrangement electrodes being the first interval, in the second state, a second resonance frequency of the resonator is determined based on the interval between the plurality of arrangement electrodes being the second interval, and the second resonance frequency is higher than the first resonance frequency.

According to some aspects of the disclosure, a resonator drive method comprise; driving a third electrode that is higher than the first electrode and the second electrode based on an upper surface of the substrate, which are spaced apart from each other at a first interval on a substrate, to descend toward the substrate; and arranging the third electrode between the first electrode and the second electrode to be in contact with the upper surface of the substrate and arranging the first electrode, the second electrode, and the third electrode to be spaced apart from one another at a second interval, wherein the second interval is less than the first interval.

According to some aspects, arranging the third electrode on one side of the second electrode; and arranging a fourth electrode to be higher than the first electrode and the second electrode based on the upper surface of the substrate and to be parallel to the third electrode and to be on another side of the second electrode on the substrate so as to be in contact with the upper surface of the substrate, wherein the first electrode, the second electrode, the third electrode, and the fourth electrode are disposed to be spaced apart from one another at the second interval.

According to some aspects, when the third electrode is driven to come into contact with the upper surface of the substrate, a fourth electrode is higher than the first electrode and the second electrode based on the upper surface of the substrate and is parallel to the third electrode.

According to some aspects, driving a fourth electrode, which is higher than the first electrode and the second electrode based on the upper surface of the substrate and is parallel to the third electrode, to move in a direction parallel to the upper surface of the substrate such that the third electrode and the fourth electrode is located between the first electrode and the second electrode, before the third electrode comes into contact with the upper surface of the substrate, driving the third electrode and the fourth electrode to descend toward the substrate, and arranging the fourth electrode to be in contact with the upper surface of the substrate between the first electrode and the second electrode and arranging the first electrode, the second electrode, the third electrode, and the fourth electrode to be spaced apart from one other at a third interval, wherein the third interval is less than the first interval and the second interval.

According to some aspects, driving the third electrode and a fourth electrode, which is higher than the first electrode and the second electrode based on the upper surface of the substrate and is parallel to the third electrode, to move in a direction parallel to the upper surface of the substrate to arrange the third electrode to be between the first electrode and the second electrode and to arrange the second electrode to be between the third electrode and the fourth electrode, driving the third electrode and the fourth electrode to descend toward the substrate, and arranging the third electrode and the fourth electrode to be in contact with the upper surface of the substrate and arranging the first electrode, the second electrode, the third electrode, and the fourth electrode to be spaced apart from one another at the second interval.

According to some aspects, a computer-readable recording medium in which a program capable of performing the method according to claim 15 is recorded.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

In addition to the above descriptions, specific effects of the present disclosure are described below while making detailed descriptions for implementing the present disclosure.

### BRIEF DESCRIPTION OF THE DRAWINGS

FIG. 1 is a perspective view illustrating a resonator according to some embodiments of the present disclosure.

FIG. 2 is a cross-sectional view taken along line A1-A1 of FIG. 1. FIG.

FIG. 3 is a perspective view illustrating a resonator according to some embodiments of the present disclosure.

FIG. 4 is a cross-sectional view taken along line A2-A2 of FIG. 3.

FIG. 5 illustrates graphs of resonance frequencies of a resonator according to some embodiments of the present disclosure.

FIG. 6 is a perspective view illustrating a resonator according to some embodiments of the present disclosure.

FIG. 7 is a cross-sectional view taken along line B1-B1 of FIG. 6.

FIG. 8 is a perspective view illustrating a resonator according to some embodiments of the present disclosure.

FIG. 9 is a cross-sectional view taken along line B2-B2 of FIG. 8.

FIG. 10 illustrates graphs of resonance frequencies of a resonator according to some embodiments of the present disclosure.

FIG. 11 is a cross-sectional view taken along line B1-B1 of FIG. 6.

FIG. 12 is a perspective view illustrating a resonator according to some embodiments of the present disclosure.

FIGS. 13A, 13B, and 13C are cross-sectional views taken along line C-C of FIG. 12.

FIG. 14 illustrates graphs of resonance frequencies of a resonator according to some embodiments of the present disclosure.

FIG. 15 is a perspective view illustrating a resonator according to some embodiments of the present disclosure.

FIG. 16 is a cross-sectional view taken along line E1-E1 of FIG. 15.

FIG. 17 is a perspective view illustrating a resonator according to some embodiments of the present disclosure.

FIGS. 18A, 18B, and 18C are cross-sectional views taken along line E2-E2 of FIG. 17.

FIG. 19 is a flowchart illustrating a resonator drive method according to some embodiments of the present disclosure.

FIG. 20 is a flowchart illustrating a resonator drive method according to some embodiments of the present disclosure.

FIG. 21 is a flowchart illustrating the resonator drive method according to some embodiments of the present disclosure.

FIG. 22 is a flowchart illustrating a resonator drive method according to some embodiments of the present disclosure.

FIG. 23 is a flowchart illustrating the resonator drive method according to some embodiments of the present disclosure.

FIG. 24 is a diagram illustrating a hardware configuration of a resonator drive device, which performs a resonator drive method, according to some embodiments of the present disclosure.

### DETAILED DESCRIPTION OF THE EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

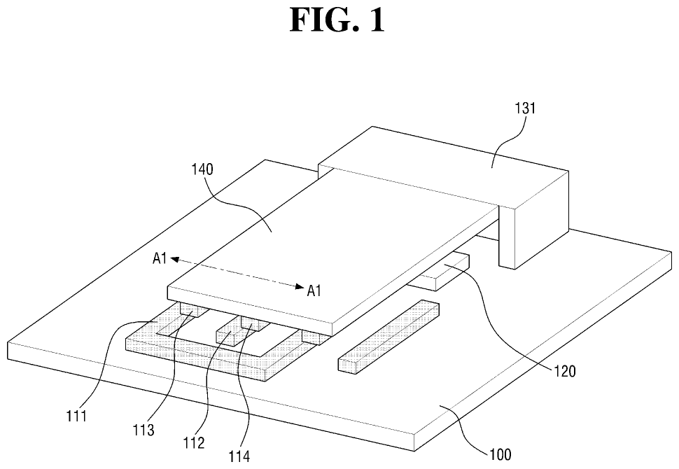

Hereinafter, a resonator according to some embodiments of the present disclosure will be described with reference to FIGS. 1 to 5.

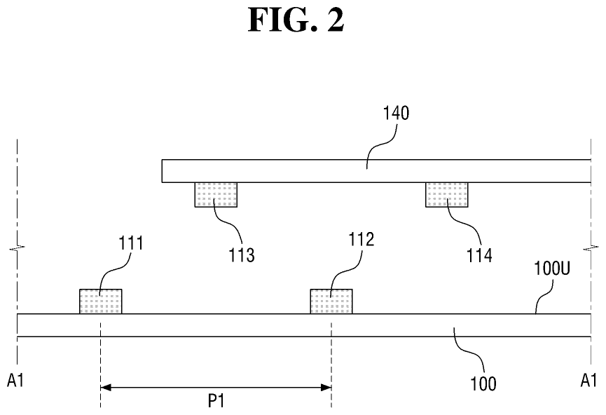

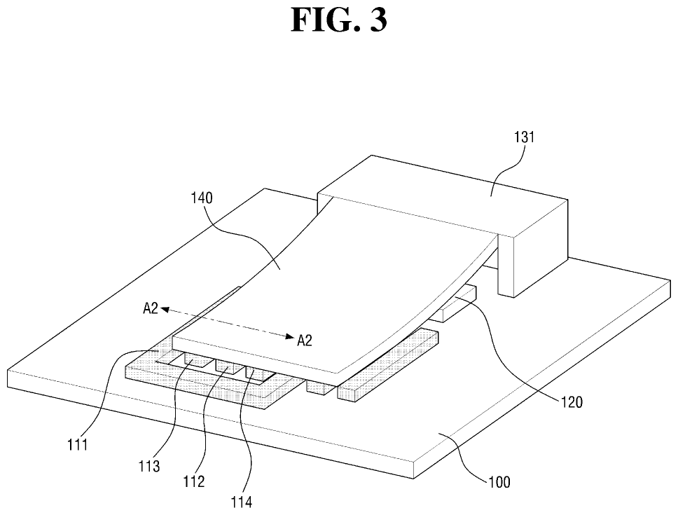

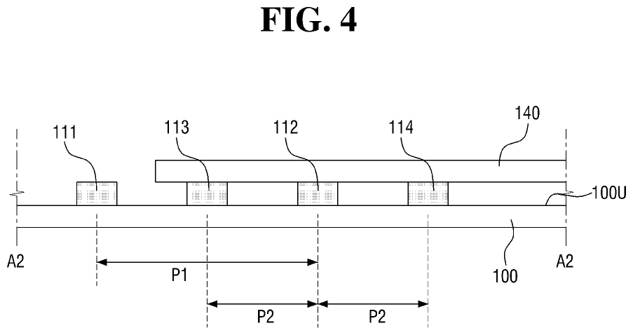

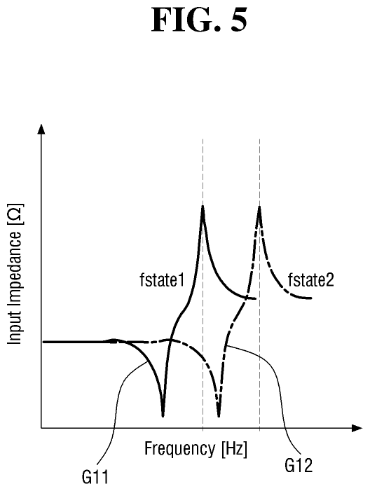

FIG. 1 is a perspective view illustrating a resonator according to some embodiments of the present disclosure. FIG. 2 is a cross-sectional view taken along line A1-A1 of FIG. 1. FIG. 3 is a perspective view illustrating a resonator according to some embodiments of the present disclosure. FIG. 4 is a cross-sectional view taken along line A2-A2 of FIG. 3. FIG. 5 illustrates graphs of resonance frequencies of a resonator according to some embodiments of the present disclosure.

Referring to FIGS. 1 and 2, a resonator according to some embodiments of the present disclosure may include a substrate 100, a first electrode 111, a second electrode 112, a third electrode 113, a fourth electrode 114, an actuator 120, a fixing portion 131, and a cantilever 140.

The fixing portion 131 may be connected to the cantilever 140 to support the cantilever 140. The fixing portion 131 may be disposed on the substrate 100.

The cantilever 140 may be connected to the first to fourth electrodes 111 to 114. For example, the third electrode 113 and the fourth electrode 114 may be attached one surface of the cantilever 140 to be in direct contact therewith.

The actuator 120 may move the cantilever 140 to actuate an electrode connected to the cantilever 140. For example, as the actuator 120 is driven, the third electrode 113 and the fourth electrode 114 connected to the cantilever 140 may be moved. For example, as the actuator 120 is driven, the third electrode 113 and the fourth electrode 114 connected to the cantilever 140 may be moved in a certain direction.

In a constant state of the resonator, the actuator 120 may adjust a plurality of arrangement electrodes disposed to be in direct contact with the substrate 100 and intervals between the plurality of arrangement electrodes. For example, in a second state of the resonator, the third electrode 113 and the fourth electrode 114 may be moved toward the substrate 100 by the actuator 120 such that the plurality of arrangement electrodes include the first electrode 111, the second electrode 112, the third electrode 113, and the fourth electrode 114. Accordingly, the intervals between the plurality of arrangement electrodes may be adjusted from a first interval P1 to a second interval P2. More detailed descriptions thereof will be made below.

Although the drawings illustrate that the actuator 120 is disposed on the substrate 100, the present disclosure is not limited thereto. For example, the actuator 120 may be located outside the resonator and electrically connected to the cantilever 140.

The plurality of arrangement electrodes may be disposed to be in contact with an upper surface 100U of the substrate 100 depending on states of the resonator. Electrodes included in the plurality of arrangement electrodes may change depending on states of the resonator. For example, in the first state, the plurality of arrangement electrodes may include the first electrode 111 and the second electrode 112, and in the second state, the plurality of arrangement electrodes may include the first electrode 111, the second electrode 112, the third electrode 113, and the fourth electrode 114.

The resonator illustrated in FIGS. 1 and 2 may be in the first state.

The first electrode 111 and the second electrode 112 may be disposed on the substrate 100 to be spaced apart from each other at the first interval P1. For example, the first electrode 111 and the second electrode 112 may be in direct contact with the upper surface 100U of the substrate 100.

The third electrode 113 and the fourth electrode 114 may be driven by the actuator 120. The third electrode 113 and the fourth electrode 114 may be connected to one surface of the cantilever 140.

The third electrode 113 may be located between the first electrode 111 and the second electrode 112. The third electrode 113 may be located on one side of the second electrode 112 on the substrate 100. The fourth electrode 114 may be located on the other side of the second electrode 112 on the substrate 100. The fourth electrode 114 may be parallel to the third electrode 113.

In the first state, the third electrode 113 and the fourth electrode 114 may be located to be higher than the first electrode 111 and the second electrode 112 based on the upper surface 100U of the substrate 100. In the first state, the plurality of arrangement electrodes may include the first electrode 111 and the second electrode 112. In the first state, a first resonance frequency of the resonator may be determined based on the first electrode 111 and the second electrode 112 of the plurality of arrangement electrodes, which are spaced apart from each other at the first interval P1.

The resonator illustrated in FIGS. 3 and 4 may be in the second state.

Referring to FIGS. 3 and 4, in the second state, the third electrode 113 may be moved toward the substrate 100 by the actuator 120. For example, the third electrode 113 may be moved in a direction toward the upper surface 100U of the substrate 100 by the actuator 120 in the second state. The third electrode 113 may be driven to be disposed between the first electrode 111 and the second electrode 112 on the substrate 100.

In some embodiments, in the second state, the fourth electrode 114 may be moved toward the substrate 100 by the actuator 120 together with the third electrode 113. For example, the fourth electrode 114 may be moved in a direction toward the upper surface 100U of the substrate 100 by the actuator 120 in the second state. The fourth electrode 114 may be driven to be disposed on the other side of the second electrode 112 on the substrate 100. For example, in the second state, the third electrode 113 may be disposed between the first electrode 111 and the second electrode 112, and the second electrode 112 may be disposed between the third electrode 113 and the fourth electrode 114.

In the second state, the plurality of arrangement electrodes may include the first electrode 111, the second electrode 112, the third electrode 113, and the fourth electrode 114. In the second state, the first electrode 111, the second electrode 112, the third electrode 113, and the fourth electrode 114 may be in direct contact with the upper surface 100U of the substrate 100.

In the second state, the plurality of arrangement electrodes may be spaced apart from each other at the second interval P2. The second interval P2 may be less than the first interval P1.

In the second state, a second resonance frequency of the resonator may be determined based on the first electrode 111, the second electrode 112, the third electrode 113, and the fourth electrode 114 of the plurality of arrangement electrodes, which are spaced apart from one another at the second interval P2.

Referring to FIG. 5, an x-axis of graphs may represent a frequency (unit: Hz), and a y-axis of the graphs may represent input impedance (unit: ohms). A first graph G11 is based on the first interval P1 of the resonator in the first state, which is illustrated in FIGS. 1 and 2. A second graph G12 is based on the second interval P2 of the resonator in the second state, which is illustrated in FIGS. 3 and 4. The resonator may have a first resonance frequency fstate1 in the first state and a second resonance frequency fstate2 in the second state. The second resonance frequency fstate2 may be higher than the first resonance frequency fstate1. That is, the second interval P2 is less than the first interval P1, and the second resonance frequency fstate2 based on the second interval P2 is higher than the first resonance frequency fstate1 based on the first interval P1.

The resonator according to some embodiments of the present disclosure may simultaneously drive electrodes (for example, the third electrode 113 and the fourth electrode 114) according to a state to adjust an arrangement electrode in contact with the upper surface 100U of the substrate 100, and by adjusting an interval between the arrangement electrodes, different resonance frequencies may be generated according to the state.

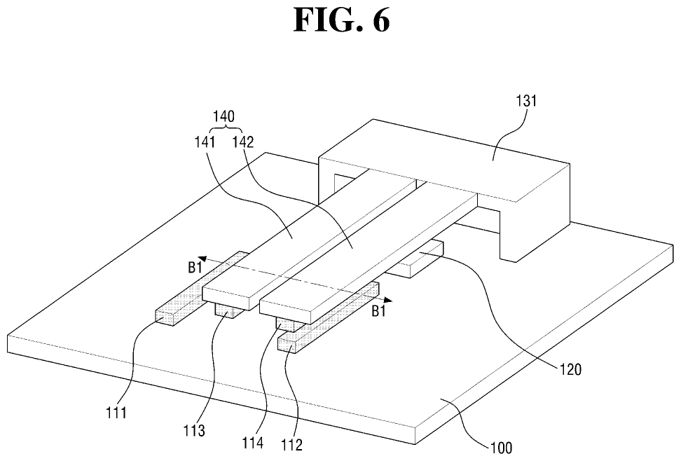

Hereinafter, resonators according to some embodiments of the present disclosure will be described with reference to FIGS. 6 to 10. For the sake of clarity of description, redundant descriptions may be simplified or omitted.

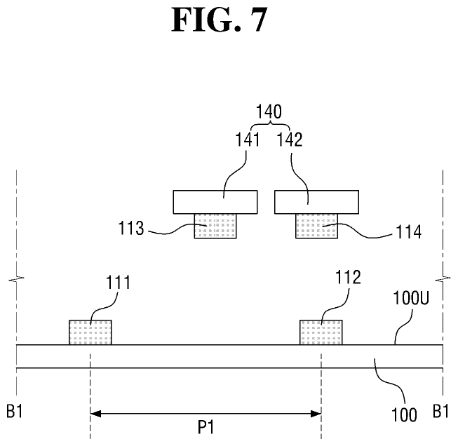

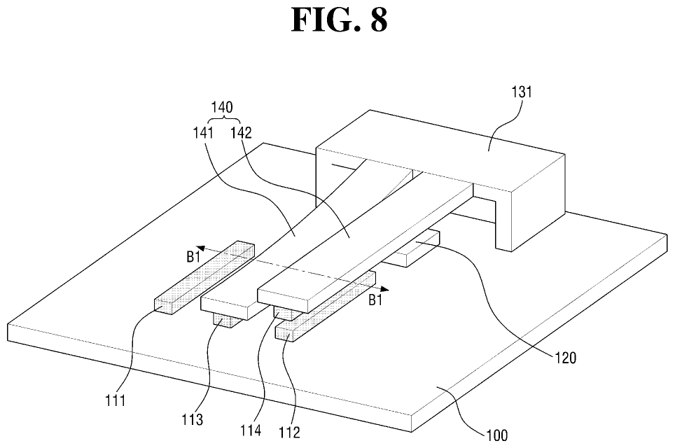

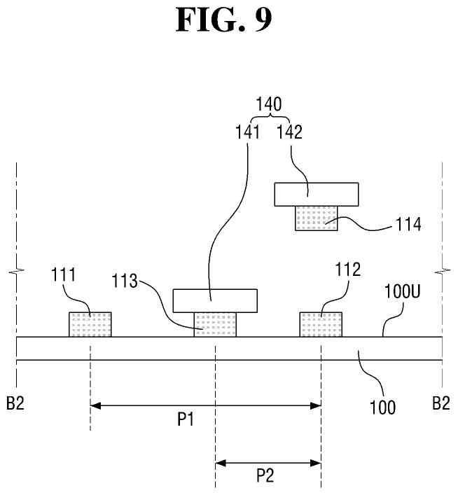

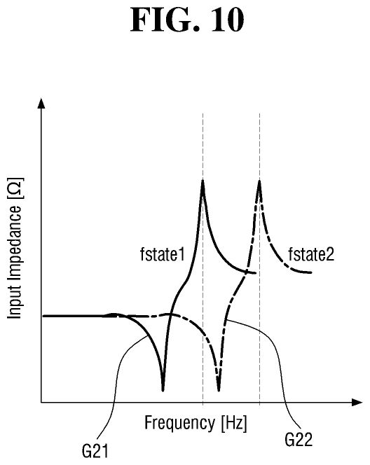

FIG. 6 is a perspective view illustrating a resonator according to some embodiments of the present disclosure. FIG. 7 is a cross-sectional view taken along line B1-B1 of FIG. 6. FIG. 8 is a perspective view illustrating a resonator according to some embodiments of the present disclosure. FIG. 9 is a cross-sectional view taken along line B2-B2 of FIG. 8. FIG. 10 illustrates graphs of resonance frequencies of a resonator according to some embodiments of the present disclosure.

Referring to FIGS. 6 and 7, a cantilever 140 of a resonator according to some embodiments of the present disclosure may include a first portion 141 and a second portion 142. The first portion 141 and the second portion 142 may be separated from each other and driven independently of each other by the actuator 120. Accordingly, a third electrode 113 connected to the first portion 141 and a fourth electrode 114 connected to the second portion 142 may be driven and moved independently of each other.

In some embodiments, there may be provided a plurality of actuators 120. The plurality of actuators 120 may each be connected to one of the first portion 141 and the second portion 142 of the cantilever 140 and may be driven independently of each other. The resonator illustrated in FIGS. 6 and 7 may be in a first state.

In the first state, the first electrode 111 and the second electrode 112 may be disposed on the substrate 100 to be spaced apart from each other at a first interval P1. In the first state, a third electrode 113 and a fourth electrode 114 may be higher than the first electrode 111 and the second electrode 112 based on an upper surface 100U of a substrate 100. In the first state, a plurality of arrangement electrodes may include the first electrode 111 and the second electrode 112. In the first state, a first resonance frequency of the resonator may be determined based on the first electrode 111 and the second electrode 112 of the plurality of arrangement electrodes, which are spaced apart from each other at the first interval P1.

The resonator illustrated in FIGS. 8 and 9 may be in a second state.

Referring to FIGS. 8 and 9, in the second state, only the first portion 141 may be driven by the actuator 120, and thereby, only the third electrode 113 among the third electrode 113 and the fourth electrode 114 may be moved toward the substrate 100. For example, the third electrode 113 may be moved in a direction toward the upper surface 100U of the substrate 100 by the actuator 120 in the second state. The third electrode 113 may be driven to be disposed between the first electrode 111 and the second electrode 112 on the substrate 100.

In some embodiments, in the second state, the fourth electrode 114 may be spaced apart from the upper surface 100U of the substrate 100 to be higher than the first electrode 111, the second electrode 112, and the third electrode 113.

In the second state, the plurality of arrangement electrodes may include the first electrode 111, the second electrode 112, and the third electrode 113. In the second state, the first electrode 111, the second electrode 112, and the third electrode 113 may be in direct contact with the upper surface 100U of the substrate 100.

In the second state, the plurality of arrangement electrodes may be spaced apart from each other at a second interval P2. The second interval P2 may be less than the first interval P1.

In the second state, a second resonance frequency of the resonator may be determined based on the first electrode 111, the second electrode 112, and the third electrode 113 of the plurality of arrangement electrodes, which are spaced apart from one another at the second interval P2.

Referring to FIG. 10, an x-axis of graphs may represent a frequency (unit: Hz), and a y-axis of the graphs may represent input impedance (unit: ohms). A third graph G21 is based on the first interval P1 of the resonator in the first state, which is illustrated in FIGS. 6 and 7. A fourth graph G22 is based on the second interval P2 of the resonator in the second state, which is illustrated in FIGS. 8 and 9. The resonator may have a first resonance frequency fstate1 in the first state and a second resonance frequency fstate2 in the second state. The second resonance frequency fstate2 may be higher than the first resonance frequency fstate1. That is, the second interval P2 may be less than the first interval P1, and the second resonance frequency fstate2 based on the second interval P2 may be higher than the first resonance frequency fstate1 based on the first interval P1.

The resonator according to some embodiments of the present disclosure may independently drives electrodes (for example, the third electrode 113 and the fourth electrode 114) according to a state to adjust an arrangement electrode in contact with the upper surface 100U of the substrate 100, and by adjusting an interval between the arrangement electrodes, different resonance frequencies may be generated according to the state.

Hereinafter, resonators according to some embodiments of the present disclosure will be described with reference to FIGS. 6, 11, 12, 13A, 13B, 13C, and 14. For the sake of clarity of description, redundant descriptions may be simplified or omitted.

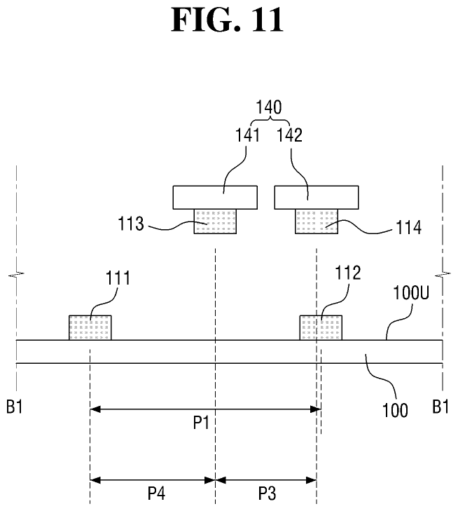

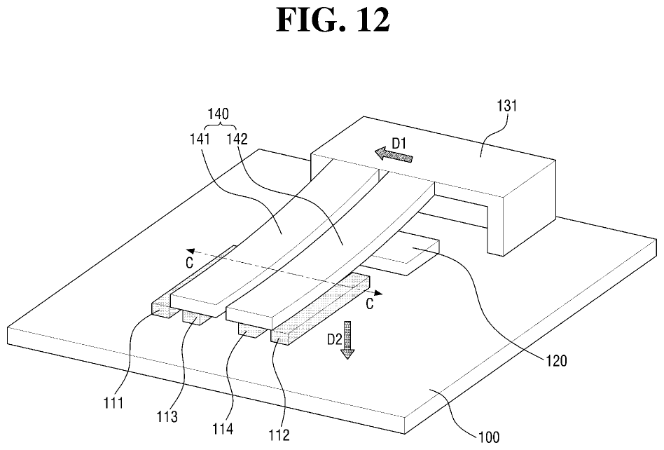

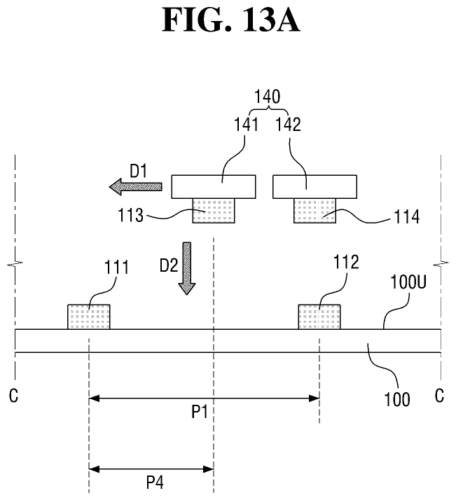

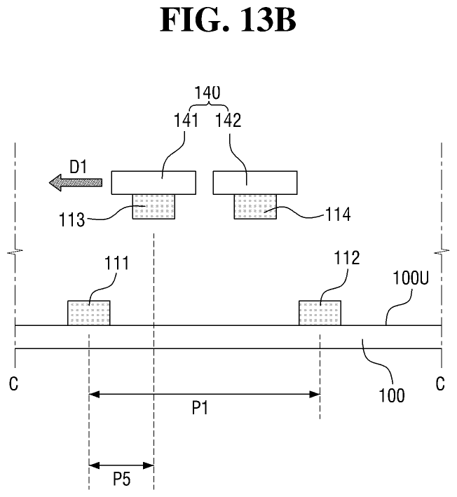

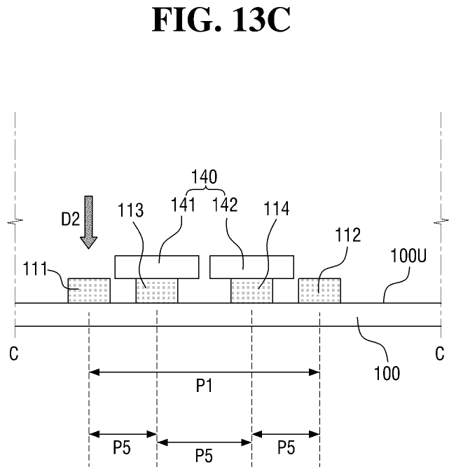

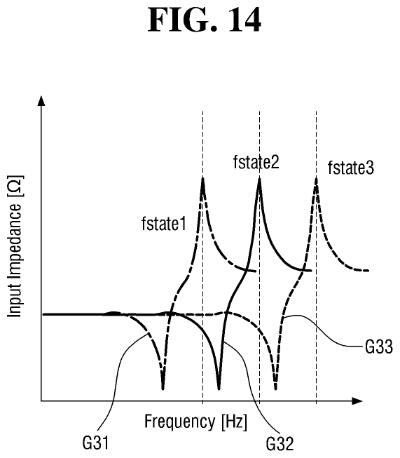

FIG. 11 is a cross-sectional view taken along line B1-B1 of FIG. 6. FIG. 12 is a perspective view illustrating a resonator according to some embodiments of the present disclosure. FIGS. 13A, 13B, and 13C are cross-sectional views taken along line C-C of FIG. 12. FIG. 14 illustrates graphs of resonance frequencies of a resonator according to some embodiments of the present disclosure.

Referring to FIGS. 6 and 11, the resonator illustrated in FIGS. 6 and 11 may be in a first state.

In the first state, a third electrode 113 and a fourth electrode 114 may be spaced apart from each other at a third interval P3 and may be higher than a first electrode 111 and a second electrode 112 based on an upper surface of the substrate 100. In the first state, the fourth electrode 114 may be closer to the second electrode 112 than the third electrode 113. For example, in the first state, a distance between the fourth electrode 114 and the second electrode 112 may be less than a distance between the third electrode 113 and the second electrode 112.

The first electrode 111 and the third electrode 113 may be spaced apart from each other at a fourth interval P4. In the first state, a first resonance frequency of the resonator may be determined based on the first electrode 111 and the second electrode 112 among a plurality of arrangement electrodes, which are spaced apart from each other at the first interval P1.

Referring to FIG. 12, a first portion 141 and a second portion 142 of the resonator according to some embodiments of the present disclosure may be moved in a first direction D1 and a second direction D2. The first direction D1 may be parallel to an upper surface 100U of the substrate 100. The second direction D2 may be a direction toward the substrate 100.

A rail may be installed in a fixing portion 131 such that the first portion 141 and the second portion 142 move in the first direction D1. A cantilever 140 may be moved in the first direction D1 along the rail.

In a second state, the first portion 141 may be driven by an actuator 120 to move the third electrode 113 in the first direction D1. As the third electrode 113 moves in the first direction D1, an interval between the first electrode 111 and the third electrode 113 may be a second interval P2. After the third electrode 113 is driven to move in the first direction D1, the third electrode 113 may be driven to move in the second direction D2. In the second state, the fourth electrode 114 may be spaced apart from the upper surface 100U of the substrate 100 and may be higher than the first electrode 111, the second electrode 112, and the third electrode 113. As illustrated in FIG. 9, in the second state, the plurality of arrangement electrodes may include the first electrode 111, the second electrode 112, and the third electrode 113. In the second state, the plurality of arrangement electrodes may be spaced apart from each other at the second interval P2. In the second state, a second resonance frequency of the resonator may be determined based on the first electrode 111, the second electrode 112, and the third electrode 113 of the plurality of arrangement electrodes spaced apart from each other at the second interval P2.

The resonator illustrated in FIGS. 12, 13A, 13B, and 13C may be in a third state.

Referring to FIGS. 12, 13A, 13B, and 13C, in the third state, the third electrode 113 and the fourth electrode 114 may be moved in the first direction D1 by the actuator 120 to be disposed between the first electrode 111 and the second electrode 112. Accordingly, an interval between the first electrode 111 and the third electrode 113 may be changed from the fourth interval P4 to a fifth interval P5. That is, the third electrode 113 and the fourth electrode 114 may be driven by the actuator 120 to move in the first direction D1 until an interval between the third electrode 113 and the first electrode 111 becomes the fifth interval P5. The fifth interval P5 may be less than the fourth interval P4. The fifth interval P5 may be less than the first interval P1 in the first state and the second interval P2 in the second state.

In a third state, the third electrode 113 and the fourth electrode 114 are moved in the first direction D1, and then the third electrode 113 and the fourth electrode 114 may be driven by the actuator 120 to move in the second direction D2. The third electrode 113 and the fourth electrode 114 may be driven to be disposed between the first electrode 111 and the second electrode 112 on the substrate 100.

In the third state, the plurality of arrangement electrodes may include the first electrode 111, the second electrode 112, the third electrode 113, and the fourth electrode 114. In the third state, the first electrode 111, the second electrode 112, the third electrode 113, and the fourth electrode 114 may be in direct contact with the upper surface 100U of the substrate 100.

In the third state, the plurality of arrangement electrodes may be spaced apart from each other at the fifth interval P5. In the third state, a third resonance frequency of the resonator may be determined based on the first electrode 111, the second electrode 112, the third electrode 113, and the fourth electrode 114 which are spaced apart from one another at the fifth interval P5 among the plurality of arrangement electrodes.

Referring to FIG. 14, an x-axis of graphs may represent a frequency (unit: Hz), and a y-axis of the graphs may represent input impedance (unit: ohms). A fifth graph G31 is based on the first interval P1 of the resonator in the first state, which is illustrated in FIGS. 6 and 11. A sixth graph G32 is based on the second interval P2 of the resonator in the second state. A seventh graph G33 is based on the fifth interval P5 of the resonator in the third state, which is illustrated in FIGS. 12, 13A, 13B, and 13C. The resonator may have a first resonance frequency fstate1 in the first state, a second resonance frequency fstate2 in the second state, and a third resonance frequency fstate3 in the third state. The third resonance frequency fstate3 may be higher than the second resonance frequency fstate2, and the second resonance frequency fstate2 may be higher than the first resonance frequency fstate1. That is, the fifth interval P5 may be less than the second interval P2, and the third resonance frequency fstate3 based on the fifth interval P5 may be higher than the second resonance frequency fstate2. In addition, the second interval P2 may be smaller than the first interval P1, and the second resonance frequency fstate2 based on the second interval P2 may be higher than the first resonance frequency fstate1 based on the first interval P1.

The resonator according to some embodiments of the present disclosure may independently drives electrodes (for example, the third electrode 113 and the fourth electrode 114) according to a state to adjust an arrangement electrode in contact with the upper surface 100U of the substrate 100, and by adjusting an interval between the arrangement electrodes, different resonance frequencies may be generated according to the state.

Hereinafter, resonators according to some embodiments of the present disclosure will be described with reference to FIGS. 5, 15, 16, 17, 18A, 18B, and 18C. For the sake of clarity of description, redundant descriptions may be simplified or omitted.

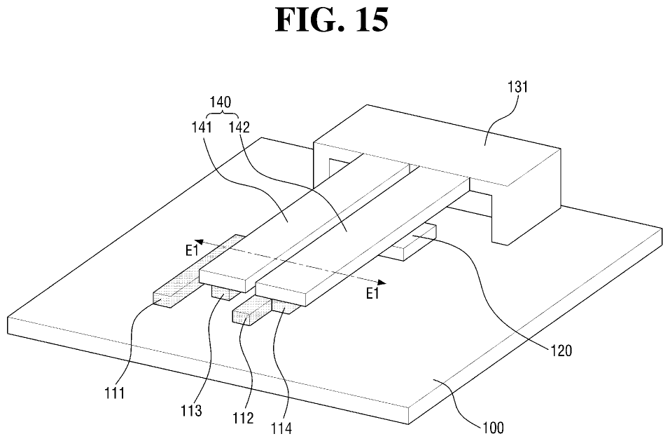

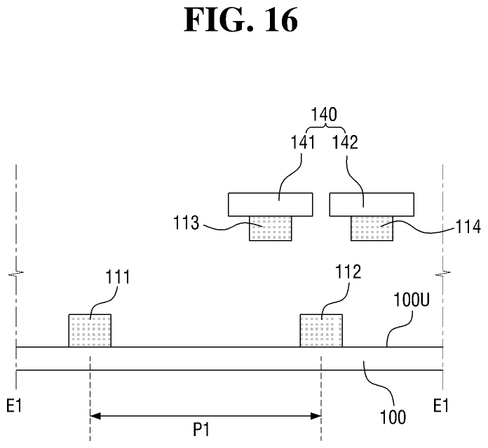

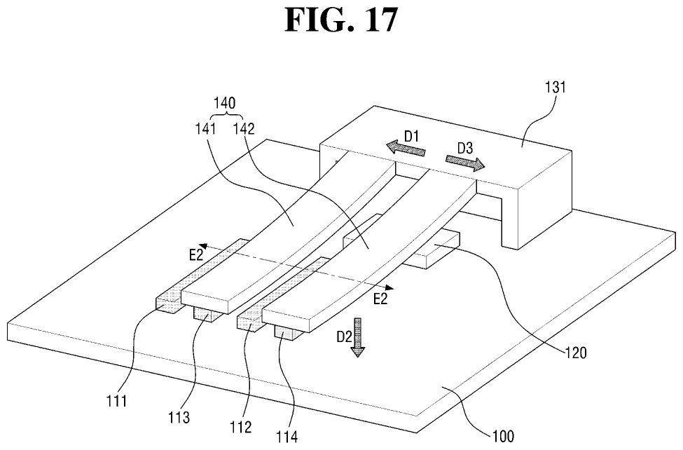

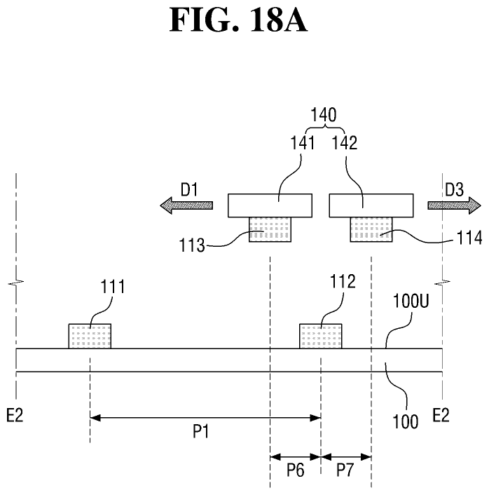

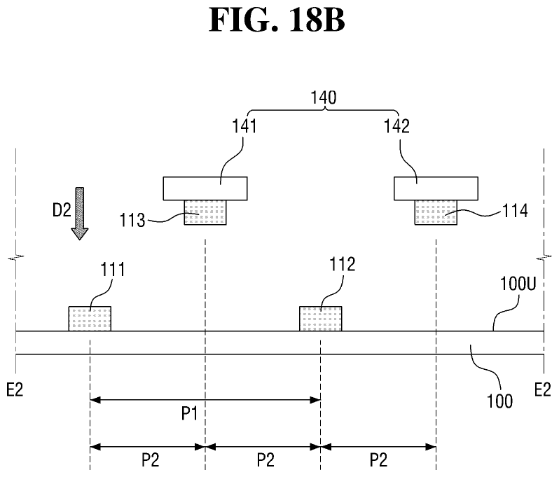

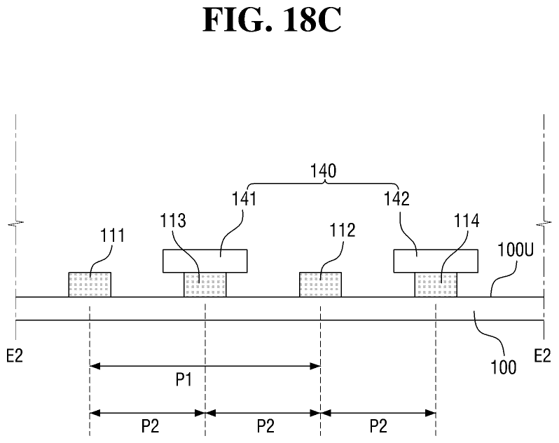

FIG. 15 is a perspective view illustrating a resonator according to some embodiments of the present disclosure. FIG. 16 is a cross-sectional view taken along line E1-E1 of FIG. 15. FIG. 17 is a perspective view illustrating a resonator according to some embodiments of the present disclosure. FIGS. 18A, 18B, and 18C are cross-sectional views taken along line E2-E2 of FIG. 17.

Referring to FIGS. 15 and 16, a resonator illustrated in FIGS. 15 and 16 may be in a first state. In the first state, a first electrode 111 and a second electrode 112 may be disposed on the substrate 100 to be spaced apart from each other at a first interval P1. In the first state, a third electrode 113 and a fourth electrode 114 may be higher than the first electrode 111 and the second electrode 112 based on an upper surface 100U of the substrate 100. In the first state, a plurality of arrangement electrodes may include the first electrode 111 and the second electrode 112. In the first state, a first resonance frequency of the resonator may be determined based on the first electrode 111 and the second electrode 112 which are spaced apart from each other at a first interval P1 among the plurality of arrangement electrodes.

Referring to FIGS. 17, 18A, 18B, and 18C, a resonator illustrated in FIGS. 17, 18A, 18B, and 18C may be in a second state.

In the first state before the third electrode 113 and the fourth electrode 114 are driven to be moved, the third electrode 113 and the second electrode 112 may be spaced apart from each other at a sixth interval P6, and the second electrode 112 and the fourth electrode 114 may be spaced apart from each other at a seventh interval P7. The sixth interval P6 and the seventh interval P7 may be equal to or different from each other. In the second state, a first portion 141 and a second portion 142 of a cantilever 140 may be moved independently of each other. In the second state, the third electrode 113 may be driven by the actuator 120 in a first direction D1 to be spaced apart at a second interval P2 from the first electrode 111 and the second electrode 112. In the second state, the fourth electrode 114 may be driven by the actuator 120 in a third direction D3 to be spaced apart at the second interval P2 from the second electrode 112.

The third direction D3 may be parallel to the upper surface 100U of the substrate 100 and opposite to the first direction D1.

In the second state, the third electrode 113 and the fourth electrode 114 may be moved in different directions, and then the third electrode 113 and the fourth electrode 114 may be driven by the actuator 120 to move in the second direction D2. Accordingly, in the second state, the plurality of arrangement electrodes may include the first electrode 111, the second electrode 112, the third electrode 113, and the fourth electrode 114. In the second state, the first electrode 111, the second electrode 112, the third electrode 113, and the fourth electrode 114 may be in direct contact with the upper surface 100U of the substrate 100. In the second state, the plurality of arrangement electrodes may be spaced apart from each other at the second interval P2. The second interval P2 may be less than the first interval P1.

In the second state, a second resonance frequency of the resonator may be determined based on the first electrode 111, the second electrode 112, and the third electrode 113 which are spaced apart from one another at the second interval P2 among the plurality of arrangement electrodes.

Referring to FIG. 5, an x-axis of graphs may represent a frequency (unit: Hz), and a y-axis of the graphs may represent input impedance (unit: ohms). The first graph G11 is based on the first interval P1 of the resonator in the first state, which is illustrated in FIGS. 15 and 16. The second graph G12 is based on the second interval P2 of the resonator in the second state, which is illustrated in FIGS. 17, 18A, 18B, and 18C. The resonator may have a first resonance frequency fstate1 in the first state and a second resonance frequency fstate2 in the second state. The second resonance frequency fstate2 may be higher than the first resonance frequency fstate1. That is, the second interval P2 is less than the first interval P1, and the second resonance frequency fstate2 based on the second interval P2 is higher than the first resonance frequency fstate1 based on the first interval P1.

The resonator according to some embodiments of the present disclosure may independently drives electrodes (for example, the third electrode 113 and the fourth electrode 114) according to a state to adjust an arrangement electrode in contact with the upper surface 100U of the substrate 100, and by adjusting an interval between the arrangement electrodes, different resonance frequencies may be generated according to the state.

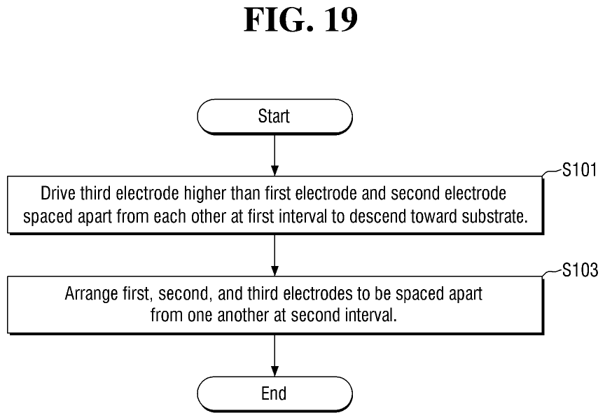

Hereinafter, a resonator according to some embodiments of the present disclosure will be described with reference to FIG. 19. For the sake of clarity of description, redundant descriptions may be simplified or omitted.

FIG. 19 is a flowchart illustrating a resonator drive method according to some embodiments of the present disclosure. FIG. 19 may be a flowchart illustrating a method of driving the resonator described with reference to FIGS. 1 to 5.

Referring to FIG. 19, the resonator drive method may include step S101 of driving a third electrode, which is higher than a first electrode and a second electrode spaced apart from each other at a first interval, to descend toward a substrate. The resonator drive method may include step S103 of driving the third electrode to descend toward the substrate and then arranging the first, second, and third electrodes to be spaced apart from one another at a second interval.

As described with reference to FIGS. 1 to 5, a first resonance frequency may be determined by the first interval between the first electrode and the second electrode in a first state of the resonator. By driving the third electrode to descend toward the substrate by an actuator in step S101, the third electrode may be disposed between the first electrode and the second electrode to come into direct contact with an upper surface of the substrate. Accordingly, as in step S103, the first electrode, the second electrode, and the third electrode may be disposed to be spaced apart from each other at the second interval.

The first resonance frequency based on the first interval may be lower than a second resonance frequency based on the second interval.

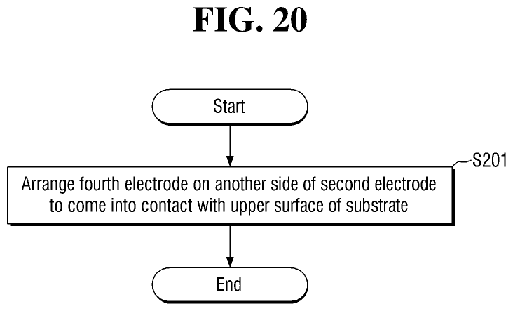

Hereinafter, a resonator according to some embodiments of the present disclosure will be described with reference to FIG. 20. For the sake of clarity of description, redundant descriptions may be simplified or omitted.

FIG. 20 is a flowchart illustrating a resonator drive method according to some embodiments of the present disclosure. FIG. 20 may be a flowchart illustrating a method of driving the resonator described with reference to FIGS. 1 to 5.

Referring to FIG. 20, the resonator drive method may further include step S201 of arranging a fourth electrode on the other side of a second electrode to come into contact with an upper surface of a substrate by an actuator.

As described with reference to FIGS. 1 to 5, in a first state, a third electrode of the resonator may be located on one side of the second electrode. The fourth electrode parallel to the third electrode in the first state may be higher than a first electrode and the second electrode based on the upper surface of the substrate and may be located on the other side of the second electrode.

In a second state, the fourth electrode may be driven by an actuator and located on the other side of the second electrode to come into contact with the upper surface of the substrate. For example, the third electrode and the fourth electrode may be simultaneously moved in a direction toward the substrate to come into contact with the upper surface of the substrate. The first electrode, the second electrode, the third electrode, and the fourth electrode may be disposed to be spaced apart from one another at a second interval.

A first resonance frequency based on a first interval may be lower than a second resonance frequency based on the second interval.

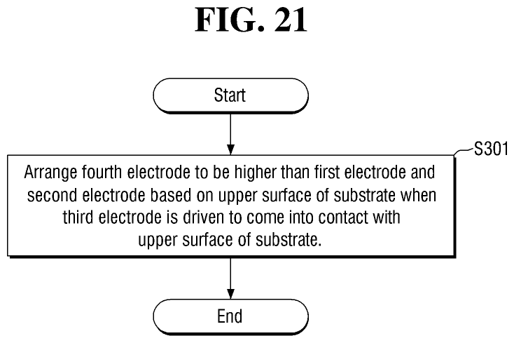

Hereinafter, a resonator drive method according to some embodiments of the present disclosure will be described with reference to FIG. 21. For the sake of clarity of description, redundant descriptions may be simplified or omitted.

FIG. 21 is a flowchart illustrating the resonator drive method according to some embodiments of the present disclosure. FIG. 21 may be a flowchart illustrating a method of driving the resonator described with reference to FIGS. 6 to 10.

Referring to FIG. 21, the resonator drive method may further include step S301 of causing a fourth electrode to be higher than a first electrode and a second electrode based on an upper surface of a substrate when a third electrode is driven by an actuator to come into contact with the upper surface of the substrate.

As described with reference to FIGS. 6 to 10, in a first state, the first electrode and the second electrode may be spaced apart from each other at a first interval. The third electrode and the fourth electrode may be higher than the first electrode and the second electrode based on the upper surface of the substrate. In the first state, a plurality of arrangement electrodes may include the first electrode and the second electrode. For example, the first electrode and the second electrode may be in contact with the upper surface of the substrate.

In a second state, the third electrode may be driven by the actuator to move toward the substrate and come into contact with the upper surface of the substrate. Accordingly, the plurality of arrangement electrodes may include the first electrode, the second electrode, and the third electrode. The third electrode may be disposed between the first electrode and the second electrode. In the second state, the plurality of arrangement electrodes may be spaced apart from each other at a second interval.

In the second state, the fourth electrode may not move toward the substrate. In the second state, the fourth electrode may be higher than the first electrode and the second electrode based on the upper surface of the substrate.

A first resonance frequency based on the first interval may be lower than a second resonance frequency based on the second interval.

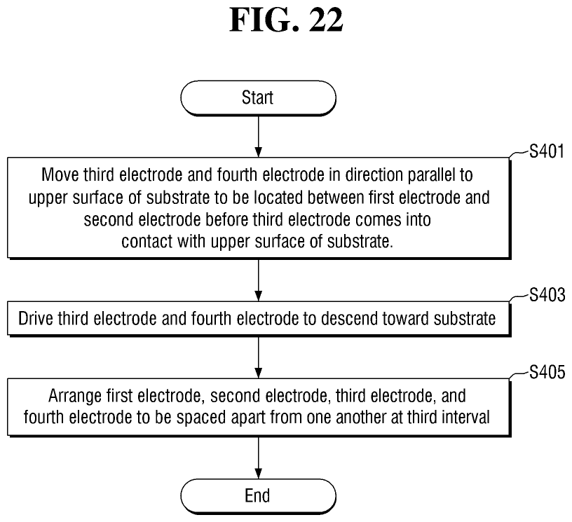

Hereinafter, a resonator according to some embodiments of the present disclosure will be described with reference to FIG. 22. For the sake of clarity of description, redundant descriptions may be simplified or omitted.

FIG. 22 is a flowchart illustrating a resonator drive method according to some embodiments of the present disclosure. FIG. 22 may be a flowchart illustrating a method of driving the resonator described with reference to FIGS. 6, 11, 12, 13a, 13b, 13c, and 14.

Referring to FIG. 22, the resonator drive method may further include step S401 of moving, by an actuator, a third electrode and a fourth electrode in a direction parallel to an upper surface of a substrate to cause the third electrode and the fourth electrode to be located between a first electrode and a second electrode before the third electrode comes into contact with the upper surface of the substrate.

As described with reference to FIGS. 6, 11, 12, 13A, 13B, 13C, and 14, the first electrode and the second electrode may be spaced apart from each other at a first interval in a first state. The third electrode and the fourth electrode may be higher than the first electrode and the second electrode based on the upper surface of the substrate. In a first state, a plurality of arrangement electrodes may include the first electrode and the second electrode. The first electrode 111 may be spaced apart from the third electrode 113 at a fourth interval, and the third electrode and the fourth electrode may be spaced apart from each other at a third interval.

In a second state, the fourth electrode may be higher than the first electrode, the second electrode, and the third electrode based on the upper surface of the substrate. In the second state, the plurality of arrangement electrodes may include the first electrode, the second electrode, and the third electrode. In the second state, the plurality of arrangement electrodes may be spaced apart from each other at a second interval.

In a third state, the third electrode and the fourth electrode may be moved in a first direction by an actuator. As the third electrode and the fourth electrode move in the first direction, the first electrode and the third electrode may be spaced apart from each other at a fifth interval.

The resonator drive method may further include step S403 of driving the third electrode and the fourth electrode to descend toward the substrate by the actuator. The resonator drive method may further include step S405 of driving the first electrode, the second electrode, the third electrode, and the fourth electrode to be spaced apart from one another at the third interval by the actuator.

Accordingly, in the third state, the plurality of arrangement electrodes may include the first electrode, the second electrode, the third electrode, and the fourth electrode. In the third state, the plurality of arrangement electrodes may be spaced apart from each other at the fifth interval. The fifth interval may be less than the first interval and the second interval.

A first resonance frequency based on the first interval may be lower than a second resonance frequency based on the second interval. A third resonance frequency based on the fifth interval may be higher than the second resonance frequency.

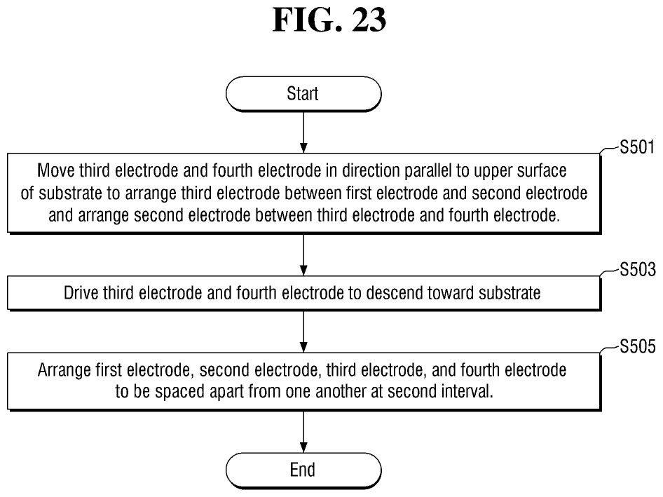

Hereinafter, a resonator drive method according to some embodiments of the present disclosure will be described with reference to FIG. 23. For the sake of clarity of description, redundant descriptions may be simplified or omitted.

FIG. 23 is a flowchart illustrating the resonator drive method according to some embodiments of the present disclosure. FIG. 23 may be a flowchart illustrating a method of driving the resonator described with reference to FIGS. 5, 15, 16, 17, 18A, 18B, and 18C.

Referring to FIG. 23, the resonator drive method may further include step S501 of moving a third electrode and a fourth electrode in a direction parallel to an upper surface of a substrate by an actuator to arrange the third electrode between the first electrode and the second electrode and arrange the second electrode between the third electrode and the fourth electrode.

As described with reference to FIGS. 5, 15, 16, 17, 18A, 18B, and 18C, in a first state, the first electrode and the second electrode may be spaced apart from each other at a first interval. The third electrode and the fourth electrode may be higher than the first electrode and the second electrode based on the upper surface of the substrate. In the first state, a plurality of arrangement electrodes may include the first electrode and the second electrode. The third electrode may be spaced apart from the second electrode at a sixth interval, and the second electrode and the fourth electrode may be spaced apart from each other at a seventh interval.

In a second state, the third electrode may be driven by the actuator to move in a first direction such that an interval between the first electrode and the third electrode is a second interval, and the fourth electrode may be moved in a third direction opposite to the first direction such that an interval between the second electrode and the fourth electrode is the second interval. Accordingly, in the second state, the third electrode may be disposed between the first electrode and the second electrode, and the second electrode may be disposed between the third electrode and the fourth electrode.

The resonator drive method may further include step S503 of driving the third electrode and the fourth electrode to descend toward the substrate by the actuator. The resonator drive method may further include step S505 of arranging the first electrode, the second electrode, the third electrode, and the fourth electrode to be spaced apart from one another at the second interval.

Accordingly, in the second state, the plurality of arrangement electrodes may include the first electrode, the second electrode, the third electrode, and the fourth electrode. In the second state, the plurality of arrangement electrodes may be spaced apart from each other at the second interval.

A first resonance frequency based on the first interval may be lower than a second resonance frequency based on the second interval.

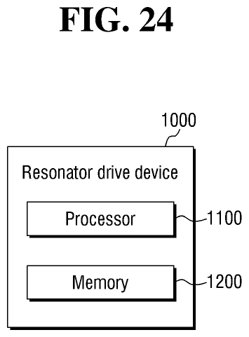

Hereinafter, a resonator according to some embodiments of the present disclosure will be described with reference to FIG. 24. For the sake of clarity of description, redundant descriptions may be simplified or omitted.

FIG. 24 is a diagram illustrating a hardware configuration of a resonator drive device, which performs a resonator drive method, according to some embodiments of the present disclosure.

In the present disclosure, a resonator drive device 1000 may be included in the actuator 120 described above or may be a separate device connected to the actuator 120.

Referring to FIG. 24, the resonator drive device 1000, which performs a resonator drive method, according to some embodiments of the present disclosure, includes a processor 1100 and a memory 1200.

Here, the processor 1100 may include at least one of a central processing unit (CPU), a micro-processor unit (MPU), a micro controller unit (MCU), a graphic processing unit (GPU), a microprocessor, a digital signal processor, a microcontroller, an application processor (AP), and logic elements capable of performing similar functions thereof. In this case, the processor 1100 may perform an operation of executing instructions included in a computer program stored in the memory 1200. Here, the computer program may include programming codes or an assembly language for performing each step of the resonator drive method described above.

For example, an actuator (for example, the actuator 120 in FIG. 1) may be driven by a computer program.

The memory 1200 may store or load data and/or computer programs. In this case, the memory 1200 may be an operating memory for improving an operation of the processor 1100 and may include high-speed dynamic random access memory (DRAM) and/or static random access memory (SRAM). In addition, the memory 1200 may include at least one non-volatile memory device, such as electrical erasable programmable ROM (EEPROM), a solid state drive (SSD), a hard drive, and flash memory, which stores data and/or computer programs.

The methods described with reference to FIGS. 15 to 19 may be implemented by software (for example, a program) including one or more instructions stored in a storage medium (for example, the memory 1200) that may be read by a machine (for example, the resonator drive device 1000). For example, the processor 1100 of a machine (for example, the resonator drive device 1000) may call at least one instruction among one or more stored instructions from a storage medium and execute the at least one instruction. This enabled the device to be operated to perform at least one function according to the at least one called instruction. The one or more instructions may include codes generated by a compiler or codes that may be executed by an interpreter. A storage medium that may be read by a machine may be provided in the form of a non-transitory storage medium. Here, the “non-transitory” means only that the storage medium is an actual device and does not include a signal (for example, an electromagnetic wave) and this term does not distinguish between a case where data is stored semi-permanently in the storage medium and a case where data is stored temporarily.

According to one embodiment, the methods described with reference to FIGS. 19 to 23 may be included in a computer program product. The computer program product is commodity and may be traded between a sellers and a buyer. The computer program product may be distributed in the form of a machine-readable storage medium (for example, a compact disc read only memory (CD-ROM)) or may be distributed (for example, downloaded or uploaded) directly or online between two user devices (for example, smartphones) through an application store (for example, Play Store™). In online distribution, at least a part of the computer program product may be temporarily stored in or temporarily generated by a machine-readable storage medium, such as memory of a manufacturer's server, an application store's server, or a relay server.

According to various embodiments, each of the above-described components (for example, an actuator, a cantilever, a substrate, and so on) may include a single entity or a plurality of entities. According to various embodiments, at least one of the components described above or at least one operation thereof may be omitted therefrom or may be added thereto. Alternatively or additionally, multiple components (for example, an actuator, a cantilever, a substrate, and so on) may be integrated into one component. In this case, the integrated component may perform one or more functions of each of the multiple components identically or similarly to the functions performed by a corresponding component among the multiple components prior to the integration. According to various embodiments, the methods described with reference to FIGS. 19 to 23 may be performed sequentially, in parallel, iteratively, or heuristically, or at least one of the operations may be performed in a different order, omitted, or one or more other operations may be added thereto.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A resonator comprising:
a substrate;
a first electrode and a second electrode disposed on the substrate at a first interval;
a plurality of arrangement electrodes disposed on the substrate, including the first electrode and the second electrode, and changing included electrodes based on a state;
an actuator configured to adjust an interval between the plurality of arrangement electrodes; and
a third electrode driven by the actuator and located between the first electrode and the second electrode,
wherein, in a first state, the third electrode is higher than the first electrode and the second electrode based on an upper surface of the substrate, and the plurality of arrangement electrodes include the first electrode and the second electrode spaced apart from each other at the first interval,
in a second state, the third electrode is moved toward the substrate by the actuator to be disposed between the first electrode and the second electrode on the substrate, and the first electrode, the second electrode, and the third electrode are spaced apart from one another at a second interval less than the first interval, and
the plurality of arrangement electrodes include the first electrode, the second electrode, and the third electrode.

2. The resonator of claim 1, wherein,
in the first state, a first resonance frequency of the resonator is determined based on the interval between the plurality of arrangement electrodes being the first interval,
in the second state, a second resonance frequency of the resonator is determined based on the interval between the plurality of arrangement electrodes being the second interval, and
the second resonance frequency is higher than the first resonance frequency.

3. The resonator of claim 1, wherein
the third electrode is located on one side of the second electrode,
the resonator further includes a fourth electrode driven by the actuator and located on another side of the second electrode,
in the first state, the fourth electrode is higher than the first electrode and the second electrode based on the upper surface of the substrate,
in the second state, the fourth electrode is moved toward the substrate by the actuator to be disposed on another side of the second electrode on the substrate, and the second electrode and the fourth electrode, which are adjacent to each other, are spaced apart from each other at the second interval, and
the plurality of arrangement electrodes include the first electrode, the second electrode, the third electrode, and the fourth electrode.

4. The resonator of claim 3, wherein,
in the second state, the first electrode, the second electrode, the third electrode, and the fourth electrode are in direct contact with the upper surface of the substrate.

5. The resonator of claim 1, wherein,
in the second state, the first electrode, the second electrode, and the third electrode are in direct contact with the upper surface of the substrate.

6. The resonator of claim 1, further comprising:
a fourth electrode driven by the actuator and located in parallel with the third electrode,
wherein, in the first state, the fourth electrode is higher than the first electrode and the second electrode based on the upper surface of the substrate, and
in the second state, the fourth electrode is spaced apart from the upper surface of the substrate and is higher than the first electrode, the second electrode, and the third electrode.

7. The resonator of claim 6, wherein,
in the second state, the first electrode, the second electrode, and the third electrode are in direct contact with the upper surface of the substrate.

8. The resonator of claim 1, further comprising:
a fourth electrode driven by the actuator and located in parallel to the third electrode,
wherein, in the first state, the fourth electrode is higher than the first electrode and the second electrode based on the upper surface of the substrate,
in the third state, the third electrode and the fourth electrode are driven by the actuator to move along a direction parallel to the upper surface of the substrate and a direction toward the substrate and disposed between the first electrode and the second electrode on the substrate, and the first electrode, the second electrode, the third electrode, and the fourth electrode are spaced apart from one another at a third interval less than the first interval and the second interval, and
the plurality of arrangement electrodes include the first electrode, the second electrode, the third electrode, and the fourth electrode.

9. The resonator of claim 8, wherein,
in the first state, the fourth electrode is closer than the second electrode than the third electrode.

10. The resonator of claim 8, wherein,
in the first state, a first resonance frequency of the resonator is determined based on the interval between the plurality of arrangement electrodes being the first interval,
in the second state, a second resonance frequency of the resonator is determined based on the interval between the plurality of arrangement electrodes being the second interval,
in the third state, a third resonance frequency of the resonator is determined based on the interval between the plurality of arrangement electrodes being the third interval, and
the third resonance frequency is higher than the second resonance frequency, and the second resonance frequency is higher than the first resonance frequency.

11. The resonator of claim 8, wherein,
in the third state, the first electrode, the second electrode, the third electrode, and the fourth electrode are in direct contact with the upper surface of the substrate.

12. The resonator of claim 1, further comprising:
a fourth electrode driven by the actuator and located in parallel to the third electrode,
wherein, in the first state, the fourth electrode is higher than the first electrode and the second electrode based on the upper surface of the substrate,
In the second state, the third electrode is driven by the actuator to move in a direction parallel to the upper surface of the substrate and then move toward the substrate such that an interval between the first electrode and the third electrode is the second interval, and the fourth electrode is driven by the actuator to move in the direction parallel to the upper surface of the substrate and then move toward the substrate such that an interval between the second electrode and the fourth electrode is the second interval, and
the second electrode is disposed between the third electrode and the fourth electrode.

13. The resonator of claim 12, wherein,
in the second state, the first electrode, the second electrode, the third electrode, and the fourth electrode are in direct contact with the upper surface of the substrate.

14. The resonator of claim 12, wherein,
in the first state, a first resonance frequency of the resonator is determined based on the interval between the plurality of arrangement electrodes being the first interval,
in the second state, a second resonance frequency of the resonator is determined based on the interval between the plurality of arrangement electrodes being the second interval, and
the second resonance frequency is higher than the first resonance frequency.

15. A resonator drive method comprising:
driving a third electrode that is higher than the first electrode and the second electrode based on an upper surface of the substrate, which are spaced apart from each other at a first interval on a substrate, to descend toward the substrate; and
arranging the third electrode between the first electrode and the second electrode to be in contact with the upper surface of the substrate and arranging the first electrode, the second electrode, and the third electrode to be spaced apart from one another at a second interval,
wherein the second interval is less than the first interval.

16. The resonator drive method of claim 15, further comprising:
arranging the third electrode on one side of the second electrode; and
arranging a fourth electrode to be higher than the first electrode and the second electrode based on the upper surface of the substrate and to be parallel to the third electrode and to be on another side of the second electrode on the substrate so as to be in contact with the upper surface of the substrate,
wherein the first electrode, the second electrode, the third electrode, and the fourth electrode are disposed to be spaced apart from one another at the second interval.

17. The resonator drive method of claim 15, wherein,
when the third electrode is driven to come into contact with the upper surface of the substrate, a fourth electrode is higher than the first electrode and the second electrode based on the upper surface of the substrate and is parallel to the third electrode.

18. The resonator drive method of claim 15, further comprising:
driving a fourth electrode, which is higher than the first electrode and the second electrode based on the upper surface of the substrate and is parallel to the third electrode, to move in a direction parallel to the upper surface of the substrate such that the third electrode and the fourth electrode is located between the first electrode and the second electrode, before the third electrode comes into contact with the upper surface of the substrate;
driving the third electrode and the fourth electrode to descend toward the substrate; and
arranging the fourth electrode to be in contact with the upper surface of the substrate between the first electrode and the second electrode and arranging the first electrode, the second electrode, the third electrode, and the fourth electrode to be spaced apart from one other at a third interval,
wherein the third interval is less than the first interval and the second interval.

19. The resonator drive method of claim 15, further comprising:
driving the third electrode and a fourth electrode, which is higher than the first electrode and the second electrode based on the upper surface of the substrate and is parallel to the third electrode, to move in a direction parallel to the upper surface of the substrate to arrange the third electrode to be between the first electrode and the second electrode and to arrange the second electrode to be between the third electrode and the fourth electrode;
driving the third electrode and the fourth electrode to descend toward the substrate; and
arranging the third electrode and the fourth electrode to be in contact with the upper surface of the substrate and arranging the first electrode, the second electrode, the third electrode, and the fourth electrode to be spaced apart from one another at the second interval.

20. A computer-readable recording medium in which a program capable of performing the method according to claim 15 is recorded.
